(19) United States
(12) Patent Application Publication
(10) Pub. No.: US 2007/0117257 A1
(43) Pub. Date: May 24, 2007

(54) ORGANIC LIGHT EMITTING DIODE DISPLAY

(76) Inventors: Hoon KIM, Hwaseong-si (KR); Un-Cheol Sung, Anyang-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/538,695

(22) Filed: Oct. 4, 2006

(30) Foreign Application Priority Data
Nov. 24, 2005 (KR) 10-2005-0112779

(51) Int. Cl. H01L 29/08; H01L 51/40; H01L 21/84

(52) U.S. Cl. 438/99; 438/149; 257/40

(57) ABSTRACT

An OLED display comprises a barrier layer to substantially block moisture from an organic material. For example, an OLED display includes a substrate, a first signal line formed on the substrate, a second signal line crossing the first signal line, a driving voltage line formed on the substrate to transfer a first voltage, a first TFT connected to the first and second signal lines, a second TFT connected to the first TFT and the drive voltage line, a passivation layer formed on the first and second TFTs, a barrier layer formed on the passivation layer, a first electrode formed on the barrier layer and connected to the second TFT, a second electrode to receive a second voltage and positioned facing the first electrode, and a light emitter member formed between the first and second electrodes. Because the barrier layer as the inorganic layer is formed on the passivation layer as the organic layer, an inflow of moisture to an organic light emitter member can be prevented (or substantially reduced). In addition, because the passivation layer is formed as the inorganic layer, moisture content of the passivation layer can be minimized, and thus the life span of the organic light emitter member can be lengthened.

### CROSS-REFERENCE TO RELATED APPLICATION

This application claims priority to and the benefit of Korean Patent Application No. 10-2005-0112779 filed in the Korean Intellectual Property Office on Nov. 24, 2005, the entire contents of which are incorporated herein by reference.

### BACKGROUND OF THE INVENTION

(a) Field of the Invention

The present invention relates to an organic light emitting diode (OLED) display.

(b) Description of the Related Art

Recently, with increased demand for light and thin monitors and televisions, cathode ray tubes (CRTs) are being replaced by liquid crystal displays (LCDs).

However LCDs, which are light emitting and receiving devices, are disadvantageous in that they require backlight. Additionally, LCDs have a number of problems regarding response speed and viewing angle.

Thus, lately, OLED displays have received much attention as a type of display device that can overcome the problems of the LCDs.

An OLED display includes two electrodes, and an emission layer positioned therebetween. In an OLED display, electrons injected from one electrode and holes injected from the other electrode are combined in the emission layer to form exitons, and as the exitons discharge energy, the OLED display is illuminated.

An OLED display is a self-illumination type of display that does not use a light source, so it provides advantages in terms of power consumption. OLED displays also have excellent response speed, viewing angle, and contrast ratio.

The above information disclosed in this Background section is only for enhancement of understanding of the background of the invention and therefore it may contain information that does not form the prior art that is already known in this country to a person of ordinary skill in the art.

### SUMMARY OF THE INVENTION

An exemplary embodiment of the present invention provides an OLED display including: a substrate; a first signal line formed on the substrate; a second signal line crossing the first signal line; a drive voltage line formed on the substrate to transfer a first voltage; a first thin film transistor (TFT) connected to the first and second signal lines; a second TFT connected to the first TFT and the drive voltage line; a passivation layer formed on the first and second TFTs; a barrier layer formed on the passivation layer; a first electrode formed on the barrier layer and connected to the second TFT; a second electrode to receive a second voltage and positioned facing the first electrode; and a light emitter member formed between the first and second electrodes.

The barrier layer can be formed as an inorganic layer or as a mixture thin film including an inorganic insulator and an organic insulator.

One or more additional passivation layers and barrier layers can be formed alternately on the passivation layer and the barrier layer.

The OLED may further include a partition surrounding the light emitter member.

Another embodiment of the present invention provides an OLED display including: a substrate; a first signal line formed on the substrate; a second signal line crossing the first signal line; a drive voltage line formed on the substrate to transfer a first voltage; a first TFT connected with the first and second signal lines; a second TFT connected with the first TFT and the drive voltage line; a barrier layer formed on the first and second TFTs; a first electrode formed on the barrier layer and connected to the second TFT; a second electrode to receive a second voltage and positioned facing the first electrode; and a light emitting member formed between the first and second electrodes.

In general, in another aspect, an OLED display apparatus comprises a drive thin film transistor including an output terminal in communication with a pixel electrode in a first pixel region of the display apparatus. The drive thin film transistor comprises a channel region of a semiconductor material. The apparatus further comprises a passivation layer including a portion with a first side proximate the semiconductor material of the drive thin film transistor and a second side opposite the first side, wherein the passivation layer comprises an organic material. The apparatus further comprises a barrier layer positioned proximate the second side of the portion of the passivation layer and configured to block moisture from the organic material.

The passivation layer may include a first inorganic layer proximate the first side and a second organic layer proximate the second side. The apparatus may further comprise another passivation layer proximate the barrier layer opposite the passivation layer, and may further comprise another barrier layer positioned proximate the another passivation layer. The apparatus may further comprise an organic light emitter positioned proximate the pixel electrode. The apparatus may further comprise a common electrode proximate the organic light emitter opposite the pixel electrode.

The drive thin film transistor may be included in a plurality of drive thin film transistors each in communication with a pixel electrode positioned in an associated pixel region. Each of the pixel electrodes may be in communication with organic light emitter material and configured to generate light in the organic light emitter material based on a received data signal for the associated pixel region. The apparatus may further comprise a control system to generate display signals to generate desired image parts using each of the pixel electrodes.

### BRIEF DESCRIPTION OF THE DRAWINGS

FIG. 1 is an equivalent circuit diagram of an organic light emitting diode (OLED) display according to one exemplary embodiment of the present invention.

FIG. 2 is a layout view of the OLED display according to one exemplary embodiment of the present invention.

FIGS. 3 and 4 are cross-sectional views taken along lines III-III and IV-IV of the OLED display in FIG. 2, respectively.

FIGS. 5 and 6 are cross-sectional views taken along lines III-III and IV-IV of the OLED display in FIG. 2, respectively, according to another exemplary embodiment of the present invention.

### DETAILED DESCRIPTION OF THE EMBODIMENTS

In an OLED display, a passivation layer such as an organic layer for planarization is formed on a TFT, and an organic light emitting member (which may be referred to as a light emitter) is formed on the passivation layer. In this configuration, moisture contained in the organic layer negatively affects the organic light emitting member.

One feature of the present invention provides an OLED display that is capable of preventing or substantially reducing damage to an organic light emitting member caused by an organic layer.

The present invention will now be described more fully hereinafter with reference to the accompanying drawings, in which preferred embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region or substrate is referred to as being “on” another element, it can be directly on the other element or intervening elements may also be present. In contrast, when an element is referred to as being “directly on” another element, there are no intervening elements present.

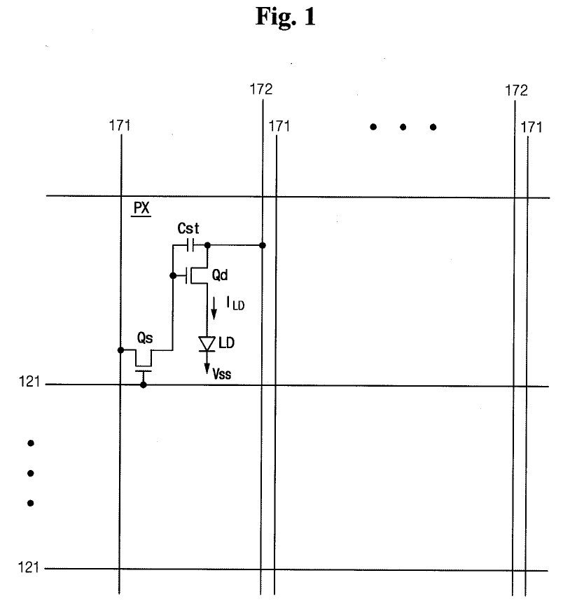

First, an OLED according to one exemplary embodiment of the present invention will be described in detail with reference to FIG. 1.

FIG. 1 is an equivalent circuit diagram of an OLED display according to one exemplary embodiment of the present invention.

With reference to FIG. 1, the OLED display according to the present exemplary embodiment of the present invention includes a plurality of signal lines 121, 171, and 172 and a plurality of pixels (PXs) formed in pixel regions of the display and connected with the plurality of signal lines 121, 171, and 172. Pixels PX are arranged substantially in a matrix form.

The signal lines include a plurality of gate lines 121 to transfer gate signals (or scan signals), a plurality of data lines 171 to transfer data signals, and a plurality of driving voltage lines 172 to transfer driving voltages. The gate lines 121 extend substantially in a row direction and are substantially parallel with each other, and the data lines 171 and the driving voltage lines 172 extend substantially in a column direction and are substantially parallel with each other.

Each pixel (PX) includes a switching transistor (Qs), a driving transistor (Qd), a storage capacitor (Cst), and an OLED LD.

The switching transistor Qs includes a control terminal, an input terminal and an output terminal. The control terminal is connected to the gate line 121, the input terminal is connected to the data line 171, and the output terminal is connected to the driving transistor Qd. The switching transistor Qs transfers a data signal applied to the data line 171 to a control terminal of the driving transistor Qd, in response to a scan signal applied to the gate line 121.

The driving transistor Qd also includes a control terminal, an input terminal, and an output terminal. The control terminal is connected to the switching transistor Qs, the input terminal is connected to the driving voltage line 172, and the output terminal is connected to the OLED LD. The driving transistor Qd outputs an output current (ILD) with a magnitude that varies depending on a voltage applied between the control terminal and the output terminal.

The capacitor Cst is connected between the control terminal and the input terminal of the driving transistor Qd. The capacitor Cst is charged using the data signals applied to the control terminal of the driving transistor Qd and sustains the data signals even after the switching transistor Qs is turned off.

The OLED LD includes an anode connected with the output terminal of the driving transistor Qd and a cathode connected to a common voltage Vss. The OLED LD generates light with an intensity that varies depending on the output current (ILD) of the driving transistor Qd, to allow displaying of images.

The switching transistor Qs and the driving transistor Qd are n-channel field effect transistors (FETs). However, in other embodiments, different switch transistor types may be used. For example, at least one of the switching transistor Qs and the driving transistor Qd can be a p-channel FET. The connection relationship of the transistors Qs and Qd, the capacitor Cst, and the OLED LD may be changed as well.

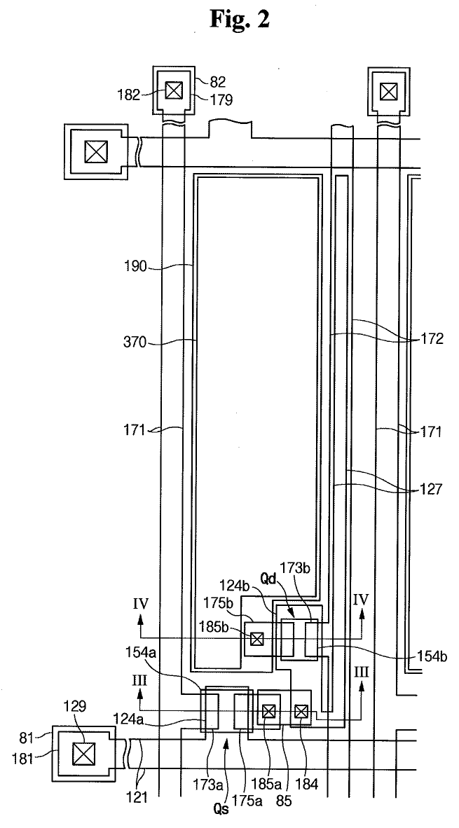

A detailed structure of the OLED display illustrated in FIG. 1 will be described in detail with reference to FIGS. 2 to 4.

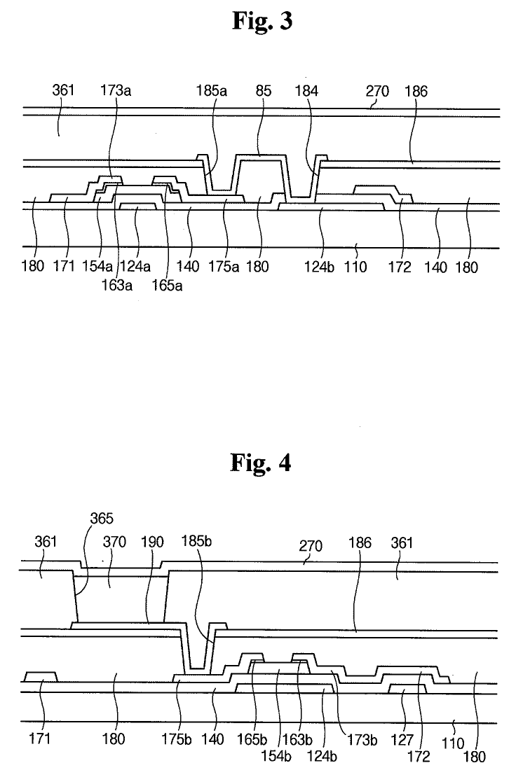

FIG. 2 is a layout view of the OLED display according to one exemplary embodiment of the present invention, and FIGS. 3 and 4 are cross-sectional views taken along lines III-III and IV-IV of the OLED display in FIG. 2, respectively.

A plurality of gate lines 121 including a plurality of first control electrodes 124a and a plurality of gate conductors including a plurality of second control electrodes 124b are formed on an insulation substrate 110 comprising a transparent material such as glass or plastic.

In the configuration shown in FIG. 2, the gate lines 121 transfer gate signals, and extend mainly in the horizontal direction. Each gate line 121 includes a large end portion 129 for a connection with a different layer or an external driving circuit, and the first control electrode 124a that extends upward from the gate line 121. When a gate driving circuit (not shown) for generating a gate signal is integrated on the substrate 110, the gate line 121 can extend to be directly connected to the gate driving circuit.

The second control electrode 124b is separated from the gate line 121, and includes a storage electrode 127 that extends in a downward direction (as illustrated in FIG. 2), changes its direction to the right side of the page, and then continuously extends upwardly.

The gate conductors 121 and 124b can be made of an aluminum group metal such as aluminum (Al) or an aluminum alloy, a silver group metal such as silver (Ag) or a Ag alloy, a copper group metal such as copper (Cu) or a copper alloy, a molybdenum group metal such as molybdenum (Mo) or a molybdenum alloy, chromium (Cr), tantalum (Ta), titanium (Ti), etc. The gate conductors 121 and 124b can have a multilayer structure including two conductive layers (not shown), each with different physical properties. One of the two conductive layers can be made of a metal with low resistivity, for example, an aluminum group metal, an Ag group metal, or a copper group metal, etc., to reduce a signal delay or a voltage drop. The other one of the two conductive layers can be made of a different material, and in particular a material that has good physical, chemical, and electrical contact characteristics with transparent conductive materials such as indium tin oxide (ITO) and indium zinc oxide (IZO); for example, a molybdenum group metal, chromium, titanium, and tantalum, etc. Good examples of the combination of two conductive materials in a multi-layer structure include a combination of a lower chromium layer and an upper aluminum (alloy) layer, and a combination of a lower aluminum (alloy) layer and an upper molybdenum (alloy) layer. In addition, the gate conductors 121 and 124b can be made of various other metals or conductors.

Preferably, the sides of the gate conductors 121 and 124b are sloped to the surface of the substrate 110, and the slope angle is within the range of 30 to 80 degrees.

A gate insulating layer 140 made of silicon nitride (SiNx) or silicon oxide (SiOx), etc., is formed on the gate conductors 121 and 124b.

A plurality of first and second semiconductor islands 154a and 154b made of hydrogenated amorphous silicon (a-Si) or polycrystalline silicon, etc., are formed on the gate insulating layer 140. The first and second semiconductor islands 154a and 154b are positioned at an upper side of the first and second control electrodes 124a and 124b, respectively.

A pair of first ohmic contacts 163a and 165a and a pair of second ohmic contacts 163b and 165b are formed on the first and second semiconductor islands 154a and 154b, respectively. The ohmic contacts 163a, 163b, 165a, and 165b have an island shape and can be made of a material such as n+hydrogenated amorphous silicon (a-Si) in which an n-type impurity such as phosphor is doped with a high density, or may comprise silicide. The first ohmic contacts 163a and 165a are disposed as a pair on the first semiconductor island 154a, and the second ohmic contacts 163b and 165b are disposed as a pair on the second semiconductor island 154b.

A plurality of data conductors including the plurality of data lines 171, a plurality of driving voltage lines 172, and a plurality of first and second output electrodes 175a and 175b are formed on the ohmic contacts 163a, 163b, 165a, and 165b and the gate insulating layer 140.

The data lines 171 transfer data signals, and extend mainly in the vertical direction of FIG. 2 to cross the gate lines 121. Each data line 171 includes a plurality of first input electrodes 173a extending toward the first control electrode 124a and a large end portion 179 for connection with a different layer or an external driving circuit. When a data driving circuit (not shown) for generating a data signal is integrated on the substrate 110, the data line 171 can extend to be directly connected with the data driving circuit.

The driving voltage line 172 transfers a driving voltage and extends mainly in the vertical direction of FIG. 2 to cross the gate line 121. Each driving voltage line 172 includes a plurality of second input electrodes 173b extending toward the second control electrode 124b. The driving voltage line 172 overlaps the storage electrode 127, and the driving voltage line 172 and the storage electrode 127 may be connected.

The first and second output electrodes 175a and 175b are separated from each other, and are also separated from the data line 171 and the driving voltage line 172. The first input electrode 173a and the first output electrode 175a face the center of the first control electrode 124a, and the second input electrode 173b and the second output electrode 175b face the center of the second control electrode 124b.

Preferably, the data conductors 171, 172, 175a, and 175b are made of a heat-resistant metal such as molybdenum, chromium, tantalum, and titanium, etc., or their alloys, and may have a multilayer structure including a heat-resistant metal film (not shown) and a low resistance conductive film (not shown). For example, the multilayer structure can include a dual-layer structure with a lower chromium or molybdenum (alloy) layer and an upper aluminum (alloy) layer, a triple-layer structure of a lower molybdenum (alloy) layer, a middle aluminum (alloy) layer, and an upper molybdenum (alloy) layer, or other appropriate multi-layer structure. In addition, the data conductors 171, 172, 175a, and 175b can be made of various other metals or conductors.

Like the gate conductors 121 and 124b, the sides of the data conductors 171, 172, 175a, and 175b are preferably sloped to the surface of the substrate 110 at a slope angle within the range of 30 to 80 degrees.

The ohmic contacts 163a, 163b, 165a, and 165b are present only between the lower semiconductor islands 154a and 154b and the upper data conductors 171, 172, 175a, and 175b, and lower contact resistance therebetween. On the semiconductor islands 154a and 154b, portions between the input electrodes 173a and 173b and the output electrodes 175a and 175b are exposed, without being covered by the data conductors 171, 172, 175a, and 175b.

A passivation layer 180 is formed on the data conductors 171, 172, 175a, and 175b and on the exposed portions of the semiconductor islands 154a and 154b. The passivation layer 180 is made of an organic insulator having planarization characteristics. In this regard, the passivation layer 180 can have a dual-layer structure having a lower inorganic layer and an upper organic layer. Such a dual-layer structure provides excellent insulation characteristics associated with organic insulator materials, while mitigating possible harm that the materials may cause to the exposed portions of the semiconductor islands 154a and 154b.

A barrier layer such as blocking layer 186 is formed on the passivation layer 180. The blocking layer 186 is made of silicon nitride (SiNx) or silicon oxide (SiO₂), etc. The blocking layer 186 serves to substantially reduce or prevent an outflow of moisture generated from the passivation layer 180 made of the organic layer to a different layer.

The blocking layer 186 can be formed as a mixture thin film by combining an organic insulator material and an inorganic insulator material. In addition, in order to further improve the moisture blocking characteristics, one or more additional passivation layers and a blocking layers can be formed alternately on the dual structure of the passivation layer 180 and the blocking layer 186.

A plurality of contact holes 182, 185a, and 185b are formed at the passivation layer 180 and the blocking layer 186 to expose the end portion 179 of the data line 171 and the first and second output electrodes 175a and 175b. At the passivation layer 180, the blocking layer 186, and the gate insulating layer 140, a plurality of contact holes 181 and 184 are formed to expose the end portion 129 of the gate line 121 and the second input electrode 124b, respectively.

A plurality of pixel electrodes 190, a plurality of connecting members 85, and a plurality of contact assistants 81 and 82 are formed on the blocking layer 186. The plurality of pixel electrodes 190, the plurality of connecting members 85, and the plurality of contact assistants 81 and 82 can be made of a transparent conductive material such as ITO or IZO, or a reflective metal such as aluminum, silver, or their alloys.

The pixel electrode 190 is physically and electrically connected to the second output electrode 175b via the contact hole 185b, and the connecting member 85 is connected to the second control electrode 124b and the first output electrode 175a via the contact holes 184 and 185a.

The contact assistants 81 and 82 are connected to the end portion 129 of the gate line 121 and the end portion 179 of the data line 171 via the contact holes 181 and 182, respectively. The contact assistants 81 and 82 complement bonding characteristics between the end portion 129 of the gate line 121 and the end portion 179 of the data line 171 and an external device, and protect them.

A partition 361 is formed on the blocking layer 186. The partition 361 defines an opening 365 by surrounding the periphery of an edge of the pixel electrode 190 like a bank. Partition 361 comprises one or more insulating materials, such as organic insulating materials or inorganic insulating materials. The partition 361 can be made of a photoresist including a black pigment. For this embodiment, the partition 361 serves as a light blocking member; additionally, its formation process is simple.

An organic light emitter such as light emitting member 370 is formed on the pixel electrode 190 in the opening 365 defined by the partition 361. The organic light emitting member 370 is made of an organic material that emits light of one of three primary colors of red, green, and blue. The OLED display displays a desired image as the spatial sum of primary color lights emanated by the organic light emitting members 370 for the pixels PX included in the OLED display.

The organic light emitting member 370 can have a multilayer structure including an emitting layer and an auxiliary layer (not shown). The auxiliary layer enhances the luminance efficiency of an emitting layer (not shown) that emits light. The auxiliary layer includes an electron transport layer (not shown) and a hole transport layer (not shown) for balancing electrons and holes, and an electron injecting layer (not shown) and a hole injecting layer (not shown) for strengthening injection of electrons and holes, etc.

In embodiments in which the blocking layer 186 is formed between the organic light emitting member 370 and the passivation layer 180, an inflow of moisture generated from the organic material of passivation layer 180 to the organic light emitting member 370 can be prevented. Thus, these embodiments provide for enhanced durability of the organic light emitting member 370.

A common electrode 270 is formed on the organic light emitting member 370. The common electrode 270 receives a common voltage Vss, and is made of a reflective metal including calcium (Ca), barium (Ba), magnesium (Mg), aluminum (Al), or silver (Ag), etc., or a transparent conductive material such as ITO, IZO, etc.

In the OLED display, the first control electrode 124a connected to the gate line 121 and the first input electrode 173a and the first output electrode 175a (which is connected with the data line 171) are included in a switch thin film transistor (TFT) Qs. The switch thin film transistor also includes a channel region that is formed at the first semiconductor island 154a between the first input electrode 173a and the first output electrode 175a.

The second control electrode 124b connected to the first output electrode 175a, the second input electrode 173b connected to the driving voltage line 172, and the second output electrode 175b connected to the pixel electrode 190 are included in a driving TFT Qd. Driving TFT Qd also includes a channel region that is formed at the second semiconductor island 154b between the second input electrode 173b and the second output electrode 175b.

The pixel electrode 190, the organic light emitting member 370, and the common electrode 270 constitute the OLED LD. In some embodiments, the pixel electrode 190 can be an anode and the common electrode 270 can be a cathode; in other embodiments, the pixel electrode 190 can be a cathode and the common electrode 270 can be an anode. The storage electrode 127 and the driving voltage line 172 that overlap with one another form the storage capacitor Cst.

The OLED display displays an image by transmitting light upward or downward with respect to the substrate 110 (upward or downward with respect to FIGS. 3 and 4). An opaque pixel electrode 190 and a transparent common electrode 270 are used for a top emission OLED display that displays images in an upward direction with respect to the substrate 110, while a transparent pixel electrode 190 and an opaque common electrode 270 are used for a bottom emission OLED display that displays images in a downward direction with respect to the substrate 110.

In some embodiments, the semiconductor islands 154a and 154b are made of polycrystalline silicon. In these embodiments, semiconductor islands 154a and 154b include an intrinsic region (not shown) facing the control electrodes 124a and 124b and extrinsic regions (impurity region) (not shown) positioned at both sides of the intrinsic region, proximate to input electrodes 173a and 173b, and output electrodes 175a and 175b. The extrinsic region are electrically connected to the input electrodes 173a and 173b and the output electrodes 175a and 175b, and the ohmic contacts 163a, 163b, 165a, and 165b can be omitted.

The control electrodes 124a and 124b can be positioned on the semiconductor islands 154a and 154b, and in this case, the gate insulating layer 140 is positioned between the semiconductor islands 154a and 154b and the control electrodes 124a and 124b. The data conductors 171, 172, 173b, and 175b are positioned at an upper portion of the gate insulating layer 140, and can be electrically connected to the semiconductor islands 154a and 154b via contact holes (not shown) formed in the gate insulating layer 140. In other embodiments, the data conductors 171, 172, 173b, and 175b can be positioned at a lower portion of the semiconductor islands 154a and 154b and can electrically contact the upper semiconductor islands 154a and 154b.

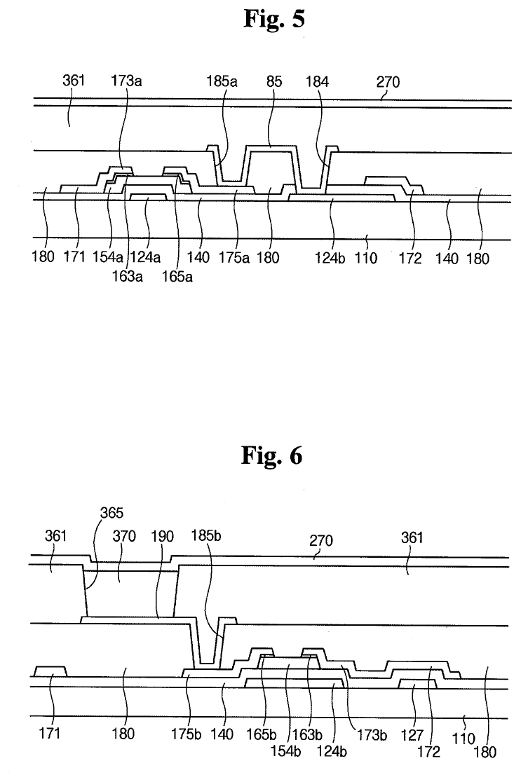

In some embodiments, the passivation layer can be directly formed as an inorganic layer with planarization characteristics. FIGS. 5 and 6 are cross-sectional views taken along lines III-III and IV-IV of the OLED display in FIG. 2, respectively, according to another exemplary embodiment of the present invention.

As shown in FIGS. 5 and 6, the OLED display according to this exemplary embodiment of the present invention is almost the same as that of the former embodiment of the present invention, except that the passivation layer 180 is formed as an inorganic layer having planarization characteristics, and no blocking layer is formed.

The passivation layer 180 is formed of an inorganic material such as silicon oxide (SiO₂) or aluminum oxide (Al₂O₂), etc. The passivation layer 180 can be formed as a moisture absorption inorganic layer that has moisture absorbing properties.

In the OLED display according to the exemplary embodiments of the present invention, using an inorganic blocking layer proximate to a passivation layer comprising an organic material, an inflow of moisture to an organic light emitting member can be prevented (or substantially reduced).

In some embodiments, the passivation layer is formed as the inorganic layer, so that the moisture content of the passivation layer can be minimized. Thus, the life span of the organic light emitting member can be lengthened.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display comprising:
a substrate;
a first signal line formed on the substrate;
a second signal line crossing the first signal line;
a drive voltage line formed on the substrate to transfer a first voltage;
a first thin film transistor (TFT) connected to the first and second signal lines;
a second TFT connected to the first TFT and the driving voltage line;
a passivation layer formed on the first and second TFTs;
a barrier layer formed on the passivation layer;
a first electrode formed on the barrier layer and connected to the second TFT;
a second electrode to receive a second voltage and facing the first electrode; and
a light emitter member formed between the first and second electrodes.

2. The OLED display of claim 1, wherein the barrier layer is formed as an inorganic layer.

3. The OLED display of claim 1, wherein the barrier layer is formed as a mixture thin film comprising an inorganic insulator and an organic insulator.

4. The OLED display of claim 1, wherein a second passivation layer and a second barrier layer are formed alternately on the passivation layer and the barrier layer.

5. The OLED display of claim 1, further comprising a partition surrounding the light emitter member.

6. An organic light emitting diode (OLED) display comprising:
a substrate;
a first signal line formed on the substrate;
a second signal line crossing the first signal line;
a drive voltage line formed on the substrate to transfer a first voltage;
a first thin film transistor (TFT) connected to the first and second signal lines;
a second TFT connected to the first TFT and the driving voltage line;
a barrier layer formed on the first and second TFTs, wherein the barrier layer is positioned and configured to substantially block moisture from being transmitted through the barrier layer;
a first electrode formed on the barrier layer and connected to the second TFT;
a second electrode to receive a second voltage and positioned facing the first electrode; and
a light emitter member formed between the first and second electrodes,
wherein the barrier layer is formed as an inorganic layer.

7. The OLED display of claim 6, wherein the barrier layer is formed directly on the first and second TFTs and is configured to act as a passivation layer.

8. The OLED display of claim 6, wherein the barrier layer is positioned proximate a passivation layer comprising an organic material.

9. The OLED display of claim 8, wherein a portion of a first side of the passivation layer is positioned adjacent a semiconductor region and a corresponding portion of a second opposite side of the passivation layer is positioned adjacent the barrier layer, and wherein the passivation layer includes an inorganic layer proximate the first side and further includes an organic layer proximate the second side.

10. The OLED device of claim 8, further comprising:
another passivation layer positioned on the block layer; and
another block layer positioned on the another passivation layer.

11. An OLED display apparatus comprising:
a drive thin film transistor including an output terminal in communication with a pixel electrode in a first pixel region of the display apparatus, the drive thin film transistor further comprising a channel region of a semiconductor material;
a passivation layer including a portion with a first side proximate the semiconductor material of the drive thin film transistor and a second side opposite the first side, wherein the passivation layer comprises an organic material; and
a barrier layer positioned proximate the second side of the portion of the passivation layer and configured to block moisture from the organic material.

12. The display apparatus of claim 11, wherein the passivation layer includes a first inorganic layer proximate the first side and a second organic layer proximate the second side.

13. The display apparatus of claim 11, further comprising another passivation layer proximate the barrier layer opposite the passivation layer.

14. The display apparatus of claim 13, further comprising another barrier layer positioned proximate the another passivation layer.

15. The display apparatus of claim 11, further comprising an organic light emitter positioned proximate the pixel electrode.

16. The display apparatus of claim 15, further comprising a common electrode proximate the organic light emitter opposite the pixel electrode.

17. The display apparatus of claim 11, wherein the drive thin film transistor is included in a plurality of drive thin film transistors each in communication with a pixel electrode positioned in an associated pixel region, wherein each of the pixel electrodes is in communication with organic light emitter material and configured to generate light in the organic light emitter material based on a received data signal for the associated pixel region.

18. The display apparatus of claim 17, further comprising a control system to generate display signals to generate desired image parts using each of the pixel electrodes.
